(19) United States
(12) Patent Application Publication
(10) Pub. No.: US 2023/0221478 A1
(43) Pub. Date: Jul. 13, 2023

(54) WIRE GATING POLARIZER AND MANUFACTURING METHOD THEREOF

(71) Applicant: GUANGZHOU LUXVISIONS INNOVATION TECHNOLOGY LIMITED, Guangzhou (CN)

(72) Inventors: Yi-Chih Lai, Guangzhou (CN); Lee-Lin Tsai, Guangzhou (CN)

(73) Assignee: GUANGZHOU LUXVISIONS INNOVATION TECHNOLOGY LIMITED, Guangzhou (CN)

(21) Appl. No.: 18/124,841

(22) Filed: Mar. 22, 2023

(30) Foreign Application Priority Data
Nov. 8, 2022 (CN) 202211389963.6

(51) Int. Cl. G02B 5/30

(52) U.S. Cl. CPC G02B 5/305; G02B 5/3058; G02B 27/0172

(57) ABSTRACT

A wire gating polarizer includes a substrate layer, a polymer wire grating layer and a plurality of coated layers. The polymer wire grating layer is disposed on the substrate layer, and includes a plurality of wire grating units. The plurality of wire grating units are formed on an upper surface of the substrate layer, and extend in a first direction. Each of the wire grating units has a top surface and respectively has a first side surface and a second side surface along two sides of the first direction. The plurality of coated layers are respectively formed on the first side surface of each of the wire grating units. The plurality of coated layers are made of a metallic or nonmetallic dielectric material. A manufacturing method of the wire grating polarizer is further provided.

### CROSS-REFERENCE TO RELATED APPLICATION

This non-provisional application claims priority under 35 U.S.C. § 119(a) to Patent Application No. 202211389963.6 filed in China on Nov. 8, 2022, the entire contents of which are hereby incorporated by reference.

### BACKGROUND

### Technical Field

The present disclosure relates to a wire gating polarizer capable of reducing damage to a wire grating structure caused by external force and a manufacturing method thereof.

### Related Art

In a display backlight module, a head-mounted virtual reality (VR) device and a projector, a wire grating polarizer is used as a reflective polarizer to separate S waves and P waves of unpolarized light beams. Traditionally, a metal wire grating structure may be directly plated onto a substrate or the wire grating structure may be disposed on the substrate, and metal is coated on the top and side surface of wire grating structure to be a wire grating polarizer.

However, the wire grating polarizer manufactured by directly plating the metal wire grating structure onto the substrate cannot use a flexible substrate and cannot achieve mass production, and its metal wire grating structure may be easily damaged by external force since it is exposed in a space. The wire grating polarizer manufactured by disposing the wire grating structure on the substrate and coating metal on the top and side surface of wire grating structure may meet the problem that the metal above the wire grating structure is exposed in the space and may be easily damaged by external force, and the separation of S wave and P wave light beams is poor.

### SUMMARY

In an embodiment, a wire gating polarizer includes a substrate layer, a polymer wire grating layer and a plurality of coated layers. The polymer wire grating layer is disposed on the substrate layer and includes a plurality of wire grating units. The plurality of wire grating units are formed on an upper surface of the substrate layer, and extend in a first direction. Each of the wire grating units has a top surface and respectively has a first side surface and a second side surface along two sides of the first direction. A plurality of coated layers are respectively formed on the first side surface of each of the wire grating units, and are made of a metallic or nonmetallic dielectric material.

In an embodiment, a manufacturing method of a wire grating polarizer, including: disposing a polymer layer on a substrate layer; imprinting the polymer layer with a mold to form a polymer wire grating layer, where the polymer wire grating layer includes a plurality of bottom layers and a plurality of wire grating units extending in a first direction, the bottom layers are respectively positioned between two adjacent wire grating units and are in contact with the upper surface of the substrate layer, each of the wire grating units has a top surface and a first side surface and a second side surface along two sides of the first direction, and an upper surface of each of the bottom layers is lower than the top surface of each of the wire grating units; depositing a metallic or nonmetallic dielectric material onto the top surface and the first side surface of each of the wire grating units; and removing the metallic or nonmetallic dielectric material deposited on the top surface of each of the wire grating units.

In an embodiment, a wire gating polarizer includes a substrate layer and a plurality of coated layers. The substrate layer includes a plurality of wire grating units extending in a first direction. Each of the wire grating units has a top surface and respectively has a first side surface and a second side surface along two sides of the first direction. A plurality of coated layers are respectively formed on the first side surface of each of the wire grating units, and are made of a metallic or nonmetallic dielectric material.

In an embodiment, a manufacturing method of a wire grating polarizer, including: imprinting an upper surface of a polymer substrate layer with a mold to form a plurality of wire grating units extending in a first direction onto an upper surface of the polymer substrate layer, where each of the wire grating units has a top surface and respectively has a first side surface and a second side surface along two sides of the first direction; depositing a metallic or nonmetallic dielectric material onto the top surface and the first side surface of each of the wire grating units; and removing the metallic or nonmetallic dielectric material deposited on the top surface of each of the wire grating units.

The present disclosure will be further illustrated in detail in conjunction with drawings and embodiments hereafter, but these illustrations are not intended to limit the present disclosure.

### BRIEF DESCRIPTION OF THE DRAWINGS

FIG. 1 is a stereoscopic diagram of an embodiment of a wire grating polarizer.

FIG. 2 is a lateral view of an embodiment of a wire grating polarizer.

FIG. 3 is a stereoscopic diagram of another embodiment of a wire grating polarizer.

FIG. 4 is a lateral view of another embodiment of a wire grating polarizer.

FIG. 5A to FIG. 5F are schematic diagrams of each step of an embodiment of a manufacturing method of a wire grating polarizer.

FIG. 6 is a flow diagram of an embodiment of a manufacturing method of a wire grating polarizer.

FIG. 7A to FIG. 7E are schematic diagrams of each step of another embodiment of a manufacturing method of a wire grating polarizer.

FIG. 8A to FIG. 8G are schematic diagrams of each step of further another embodiment of a manufacturing method of a wire grating polarizer.

FIG. 9 is a flow diagram of further another embodiment of a manufacturing method of a wire grating polarizer.

FIG. 10 is a stereoscopic diagram of further another embodiment of a wire grating polarizer.

FIG. 11 is a lateral view of further another embodiment of a wire grating polarizer.

FIG. 12A to FIG. 12F are schematic diagrams of each step of another embodiment of a manufacturing method of a wire grating polarizer.

FIG. 13 is a flow diagram of another embodiment of a manufacturing method of a wire grating polarizer.

FIG. 14 is a schematic diagram of an embodiment with an unpolarized light source emitted to a wire grating polarizer.

FIG. 15A to FIG. 15B are schematic diagrams for a height of a coated layer, a width of a wire grating unit, a spacing of a wire grating unit, a thickness of a bottom layer and a width of a coated layer.

FIG. 16 is a line chart of transmittance of S waves and transmittance of P waves of a wire grating polarizer at different widths of coated layers.

FIG. 17 is a line chart of reflectance of S waves and reflectance of P waves of a wire grating polarizer at different widths of coated layers.

FIG. 18 is a line chart of extinction ratios of a wire grating polarizer at different widths of coated layers.

FIG. 19 is a line chart of transmittance of S waves and transmittance of P waves of a wire grating polarizer at different incidence angles of an unpolarized light source.

FIG. 20 is a line chart of reflectance of S waves and reflectance of P waves of a wire grating polarizer at different incidence angles of an unpolarized light source.

FIG. 21 is a line chart of extinction ratios of a wire grating polarizer at different incidence angles of an unpolarized light source.

FIG. 22 is a schematic diagram of an embodiment using a wire grating polarizer as a backlight module of a reflective polarizer.

FIG. 23 is a schematic diagram of an embodiment using a wire grating polarizer as a head-mounted VR device of a reflective polarizer.

FIG. 24 is a lateral view of another embodiment of a wire grating polarizer.

FIG. 25 is a lateral view of another embodiment of a wire grating polarizer.

FIG. 26 is a lateral view of another embodiment of a wire grating polarizer.

FIG. 27 is a lateral view of another embodiment of a wire grating polarizer.

FIG. 28 is a lateral view of another embodiment of a wire grating polarizer.

### DETAILED DESCRIPTION

Hereinafter, the structure principles and work principles of the present disclosure will be described in detail with reference to the accompanying drawings.

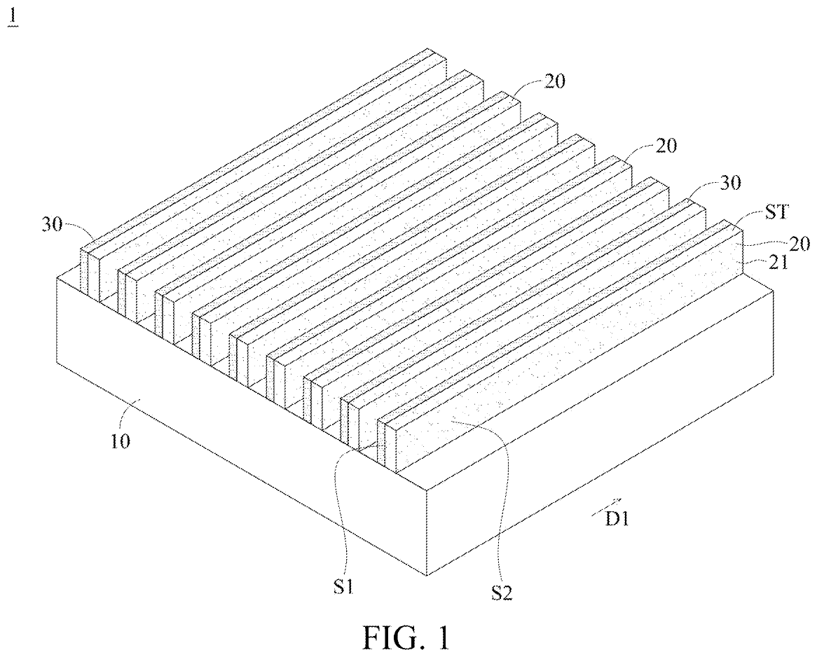

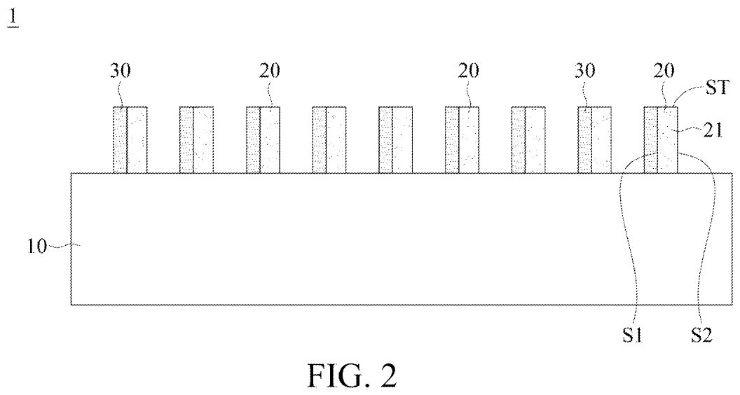

FIG. 1 is a stereoscopic diagram of an embodiment of a wire grating polarizer 1. FIG. 2 is a lateral view of an embodiment of the wire grating polarizer 1. Referring to FIG. 1 and FIG. 2, the wire grating polarizer 1 includes a substrate layer 10, a polymer wire grating layer 20 and a plurality of coated layers 30. The polymer wire grating layer 20 is disposed on the substrate layer 10 and includes a plurality of wire grating units 21. The plurality of wire grating units 21 are formed on an upper surface of the substrate layer 10 and extend in a first direction D1. The plurality of wire grating units 21 have top surfaces ST and respectively have first side surfaces S1 and second side surfaces S2 along two sides of the first direction D1. The plurality of coated layers 30 are respectively formed on the first side surface S1 of each of the wire grating units 21. In some embodiments, a shape of a cross section of each of the wire grating units 21 in a direction perpendicular to the first direction D1 is rectangular. In some embodiments, the coated layers 30 of the wire grating polarizer 1 are only formed on the first side surface S1 of each of the wire grating units 21, and the coated layers 30 of the wire grating polarizer 1 are not formed on the top surface ST of each of the wire grating units 21, so that the coated layers 30 cannot be easily damaged by external force due to exposure in a space.

In some embodiments, the material of the substrate layer 10 may be but is not limited to glass, silicon, cycloolefin copolymers (COC), cycloolefin polymers (COP), polycarbonate (PC), polyethylene terephthalate (PET), polyimide (PI), polyether sulphone (PES), polyethylene glycol naphthalate (PEN), triacetate cellulose (TAC) or polymethyl methacrylate (PMMA).

In some embodiments, the material of the polymer wire grating layer 20 may be but is not limited to silicone or PMMA.

In some embodiments, the material of the coated layers 30 may be but is not limited to a metallic dielectric material, such as gold, aluminum, silver, tantalum, copper, iridium or titanium, or a nonmetallic dielectric material, such as silicon dioxide, silicon pentoxide, titanium dioxide or silicon.

In some embodiments, the material of the substrate layer 10 is different from the material of the polymer wire grating layer 20. For example, if the material of the substrate layer 10 is PMMA, the material of the polymer wire grating layer 20 is another material being not PMMA, such as silicone.

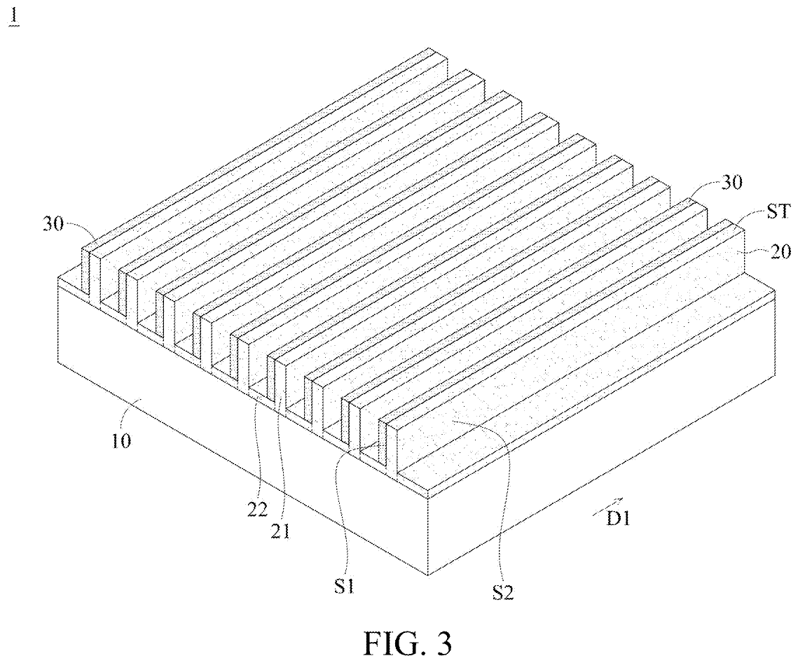

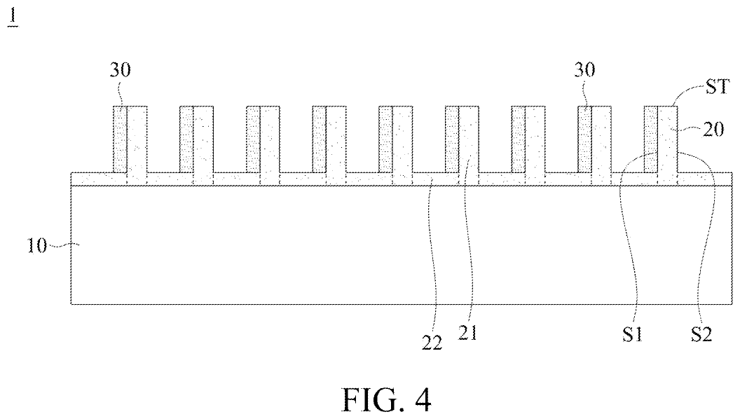

FIG. 3 is a stereoscopic diagram of another embodiment of the wire grating polarizer 1. FIG. 4 is a lateral view of another embodiment of the wire grating polarizer 1. Referring to FIG. 3 and FIG. 4, in some embodiments, the polymer wire grating layer 20 further includes a plurality of bottom layers 22. The plurality of bottom layers 22 are respectively disposed between two adjacent wire grating units 21 and are in contact with the upper surface of the substrate layer 10, and an upper surface of each of the bottom layers 22 is lower than the top surface ST of each of the wire grating units 21.

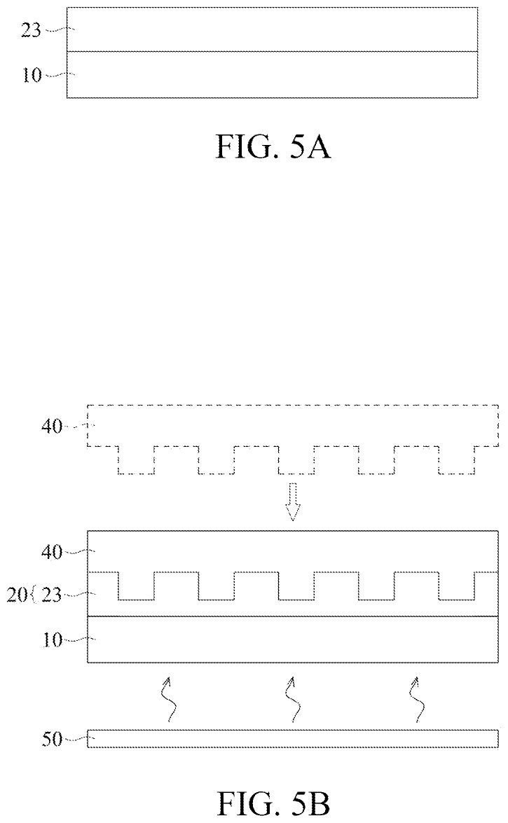

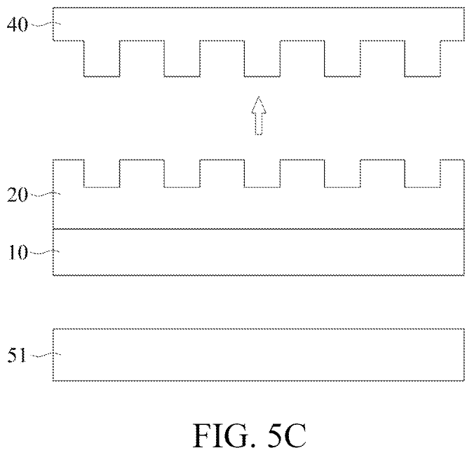

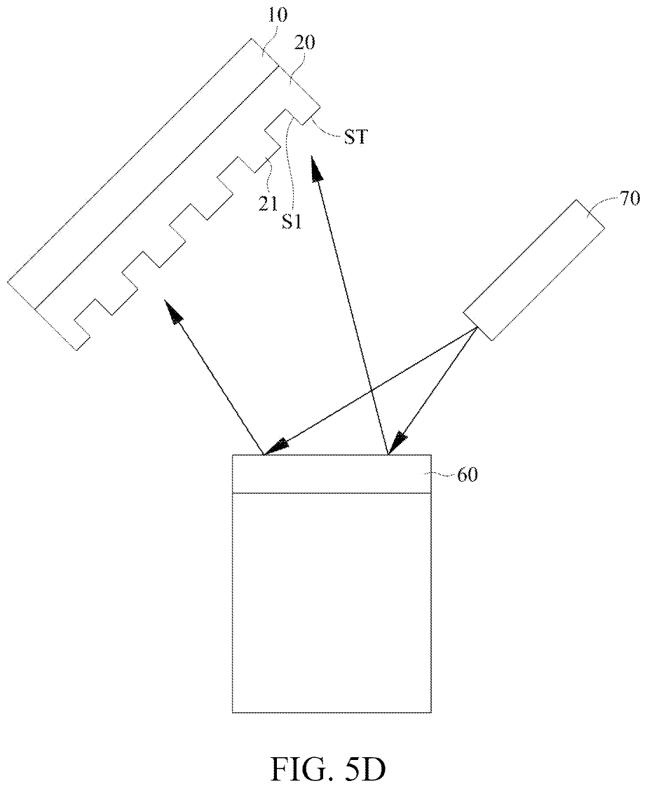

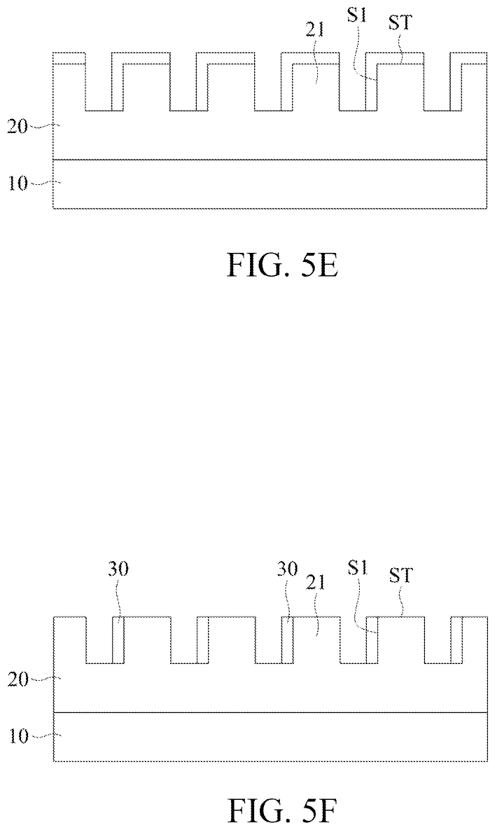

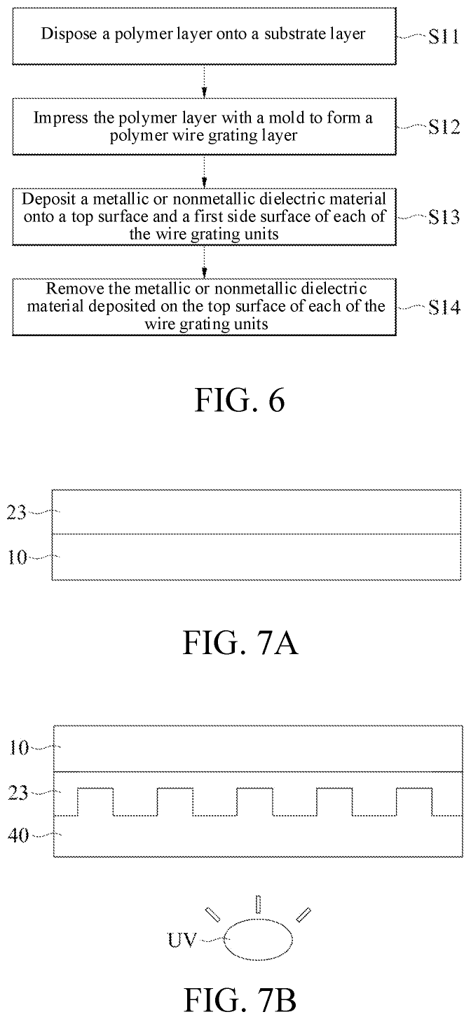

FIG. 5A to FIG. 5F are schematic diagrams of each step of an embodiment of a manufacturing method of the wire grating polarizer 1. FIG. 6 is a flow diagram of an embodiment of a manufacturing method of the wire grating polarizer 1. Referring to FIG. 3, FIG. 4, FIG. 5A to FIG. 5F and FIG. 6, firstly, a polymer layer 23 is disposed on a substrate layer 10 (Step S11). The polymer layer 23 is imprinted with a mold 40 to form a polymer wire grating layer 20 (Step S12). The polymer wire grating layer 20 includes a plurality of bottom layers 22 and a plurality of wire grating units 21 extending in a first direction D1, the plurality of bottom layers 22 are respectively positioned between two adjacent wire grating units 21 and are in contact with the upper surface of the substrate layer 10, each of the wire grating units 21 has a top surface ST and respectively has a first side surface S1 and a second side surface S2 along two sides of the first direction D1, and an upper surface of each of the bottom layers 22 is lower than the top surface ST of each of the wire grating units 21. Then, a metallic or nonmetallic dielectric material is deposited onto the top surface ST and the first side surface S1 of each of the wire grating units 21 (Step S13). Finally, the metallic or nonmetallic dielectric material deposited on the top surface ST of each of the wire grating units 21 is removed (Step S14). In some embodiments, the material of the polymer layer 23 may be but is not limited to thermoplastic polymers or thermosetting polymers.

In some embodiments, the step that the polymer layer 23 is imprinted with a mold 40 to form a polymer wire grating layer 20 includes: during imprinting, the polymer layer 23 is heated by a heater 50 so that the polymer layer 23 is cured, and after the polymer layer 23 is cured, the polymer layer 23 is cooled by a cooler S1 so that the polymer layer 23 and the mold 40 are separated to obtain the polymer wire grating layer 20.

In some embodiments, the step that metallic or nonmetallic dielectric material is deposited onto the top surface ST and the first side surface S1 of each of the wire grating units 21 may be but is not limited to a step that a target metal 60 is evaporated onto the top surface ST and the first side surface S1 of each of the wire grating units 21 by electron beams emitted from an electronic gun 70.

In some embodiments, the step that the metallic or nonmetallic dielectric material deposited on the top surface ST of each of the wire grating units 21 is removed may be but is not limited to a step that the top surface ST of each of the wire grating units 21 is subjected to plasma etching to remove the metallic or nonmetallic dielectric material from the top surface ST of each of the wire grating units 21.

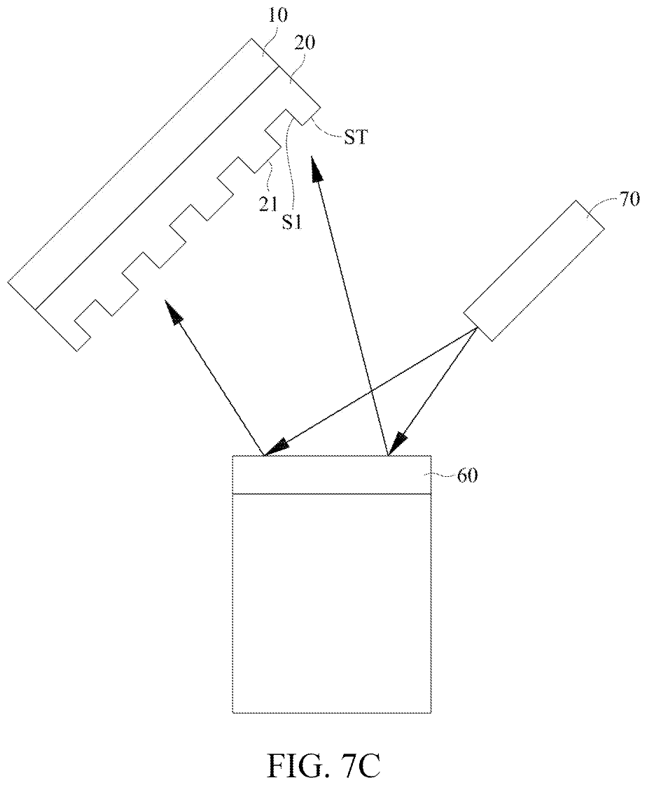

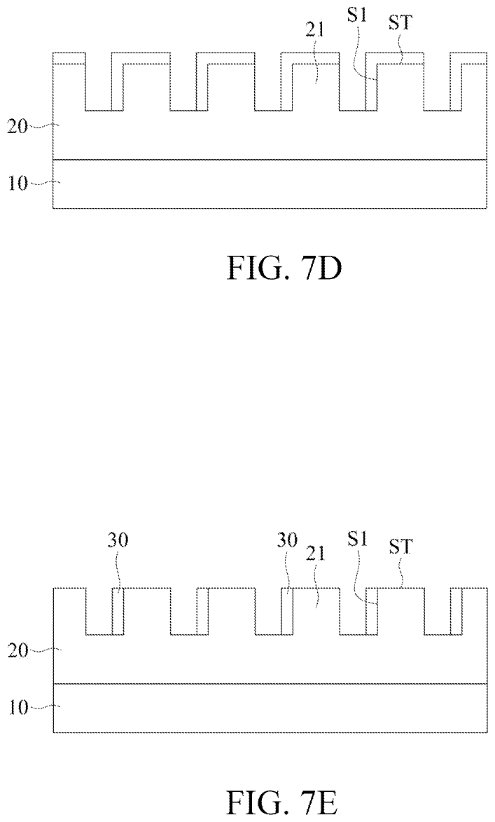

FIG. 7A to FIG. 7E are schematic diagrams of each step of another embodiment of a manufacturing method of the wire grating polarizer 1. Referring to FIG. 1, FIG. 2, FIG. 6, and FIG. 7A to FIG. 7E, in some embodiments, when the polymer layer 23 is imprinted with the mold 40 to form the polymer wire grating layer 20, the polymer layer 23 is irradiated by ultraviolet (UV) light to cure the polymer layer 23. At this moment, the material of the polymer layer 23 may be but is not limited to photocuring polymers.

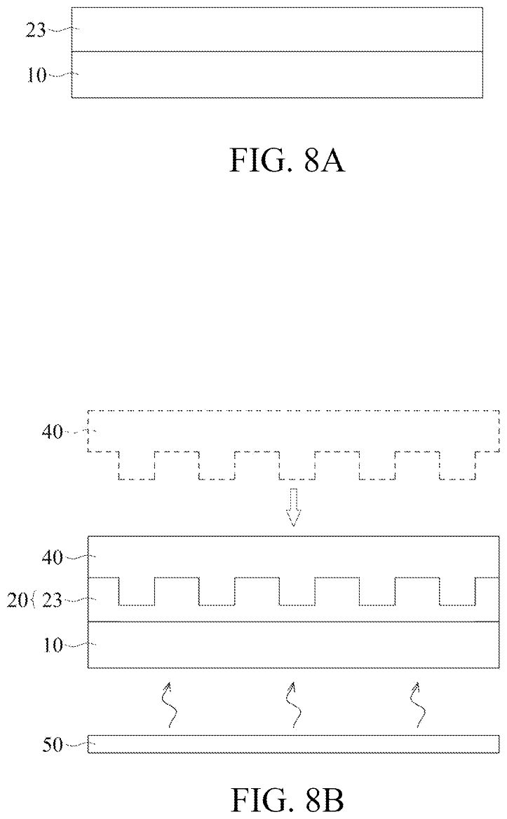

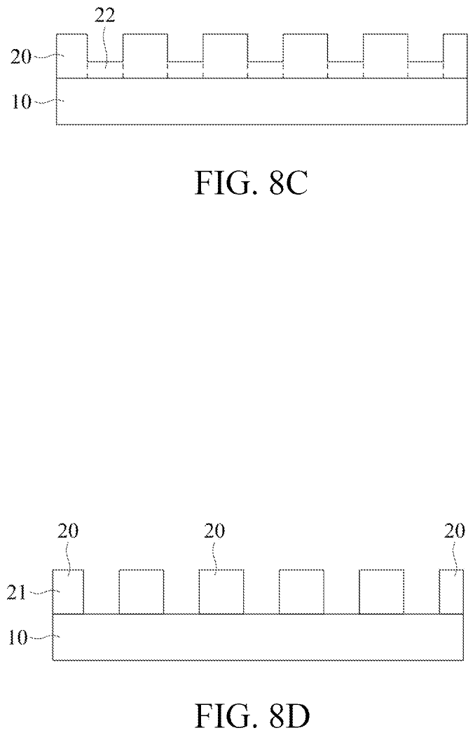

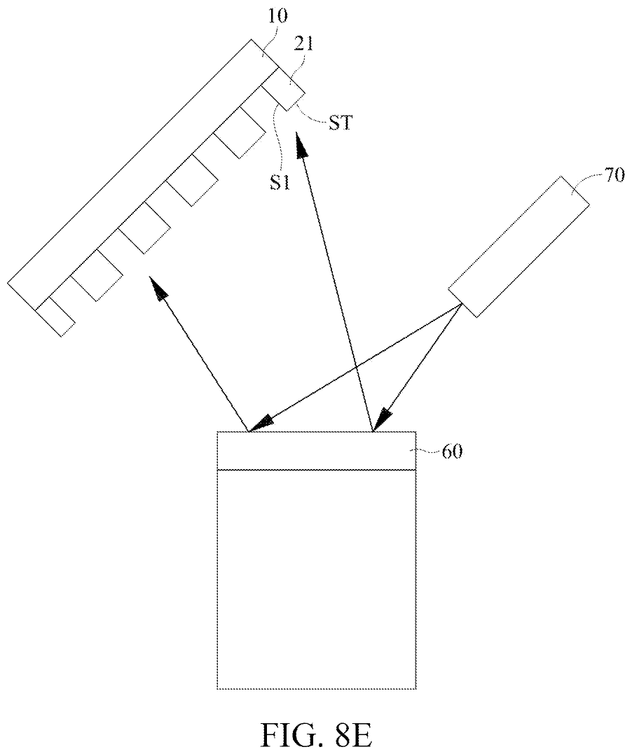

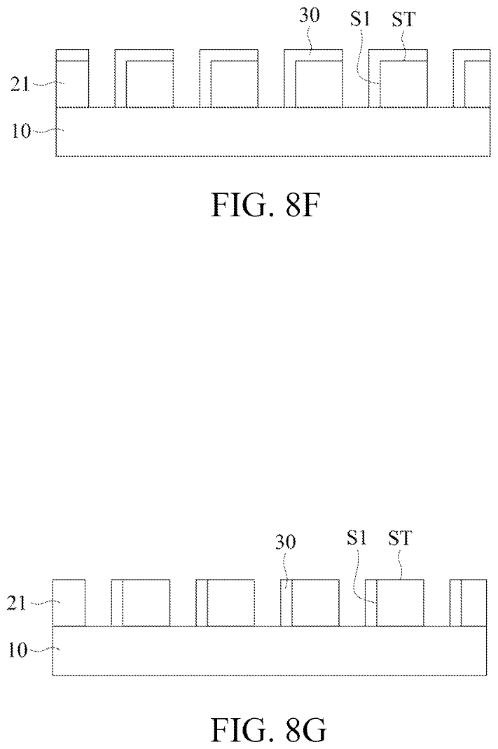

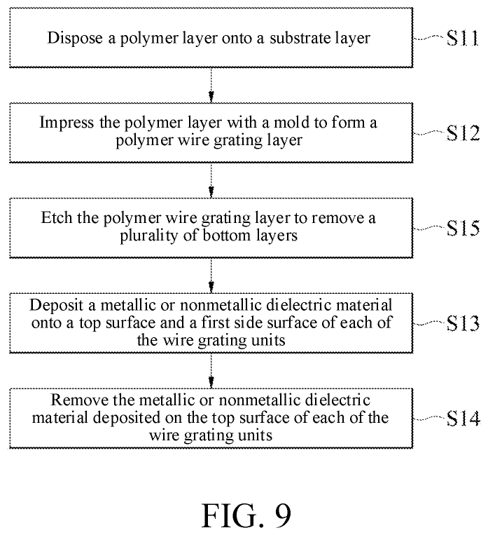

FIG. 8A to FIG. 8G are schematic diagrams of each step of further another embodiment of a manufacturing method of the wire grating polarizer 1. FIG. 9 is a flow diagram of further another embodiment of a manufacturing method of the wire grating polarizer 1. Referring to FIG. 1, FIG. 2, FIG. 8A to FIG. 8G, and FIG. 9, in some embodiments, a manufacturing method of the wire grating polarizer 1 further includes a step that the polymer wire grating layer 20 is etched to remove the plurality of bottom layers 22 (Step S15). In some embodiments, the step that the polymer wire grating layer 20 is etched to remove the plurality of bottom layers 22 may be but is not limited to a step that the polymer wire grating layer 20 is subjected to plasma etching to remove the plurality of bottom layers 22.

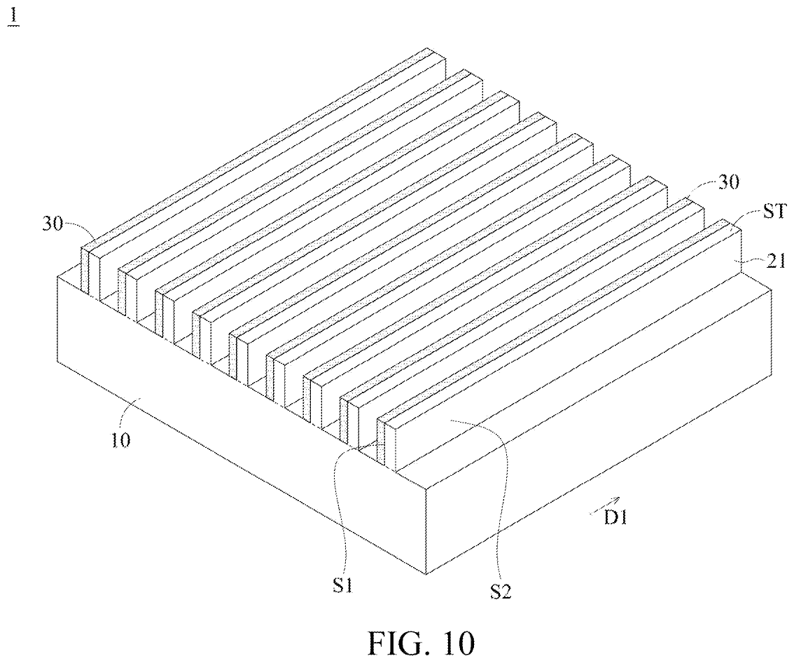

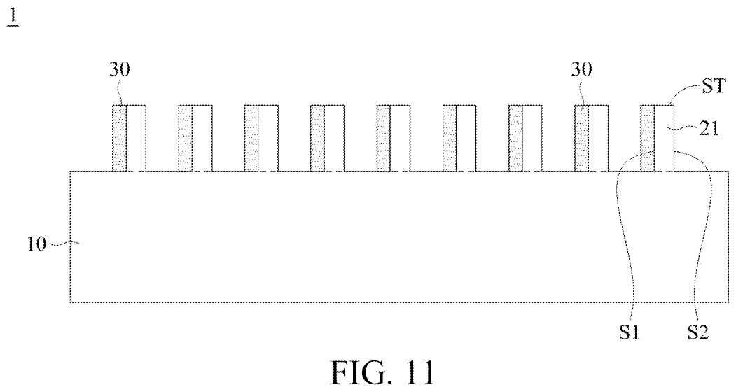

FIG. 10 is a stereoscopic diagram of further another embodiment of the wire grating polarizer 1. FIG. 11 is a lateral view of further another embodiment of the wire grating polarizer 1. Referring to FIG. 10 and FIG. 11, the wire grating polarizer 1 includes a substrate layer 10 and a plurality of coated layers 30. The substrate layer 10 includes a plurality of wire grating units 21 extending in a first direction D1. Each of the wire grating units 21 has a top surface ST and respectively has a first side surface S1 and a second side surface S2 along two sides of the first direction D1. The plurality of coated layers 30 are respectively formed on the first side surface S1 of each of the wire grating units 21, where the plurality of coated layers 30 are made of a metallic or nonmetallic dielectric material. In some embodiments, a shape of a cross section of each of the wire grating units 21 in a direction perpendicular to the first direction D1 is rectangular.

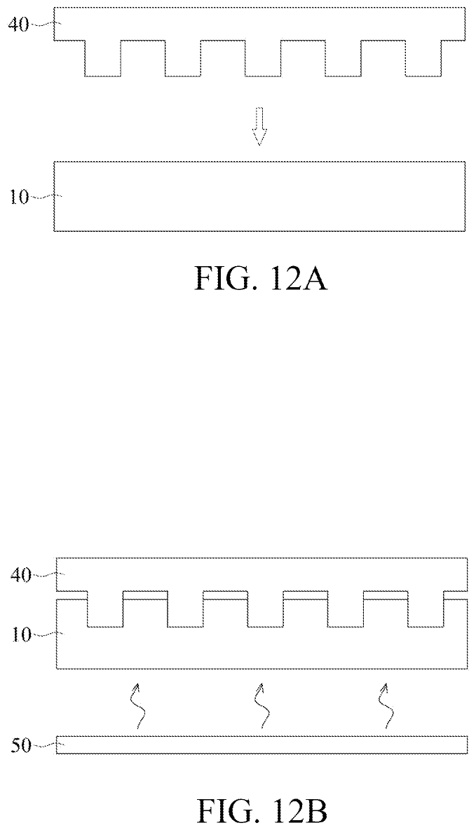

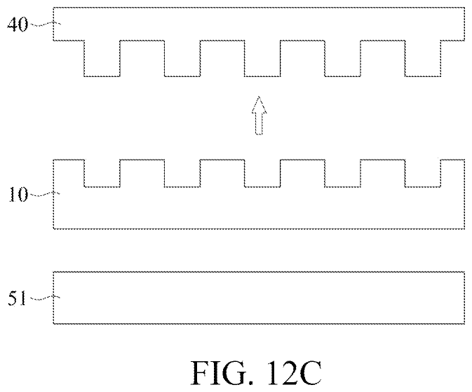

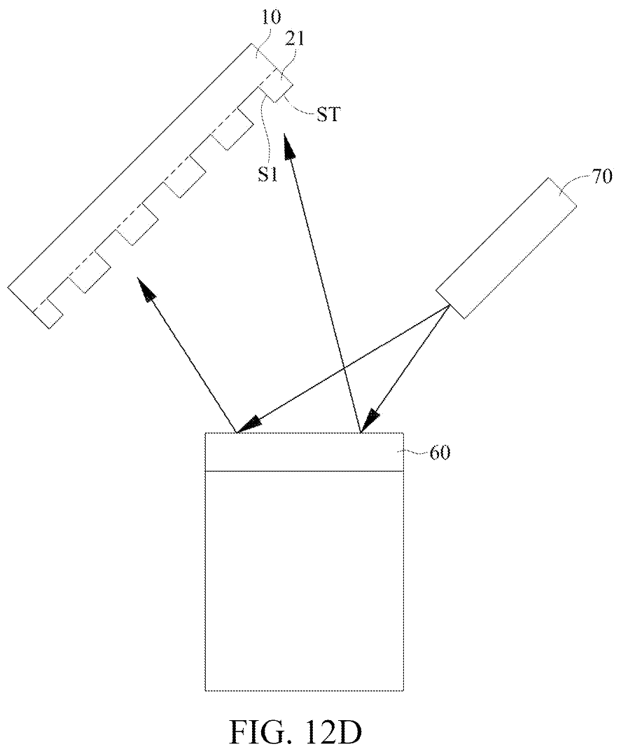

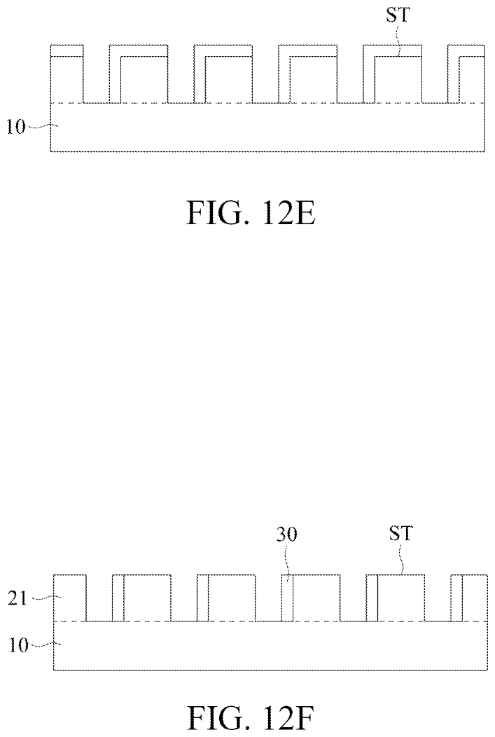

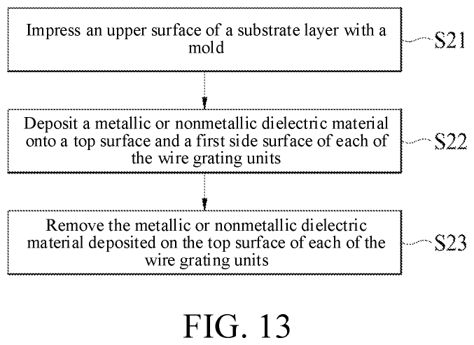

FIG. 12A to FIG. 12F are schematic diagrams of each step of another embodiment of a manufacturing method of the wire grating polarizer 1. FIG. 13 is a flow diagram of another embodiment of a manufacturing method of the wire grating polarizer 1. Referring to FIG. 10, FIG. 11, FIG. 12A to FIG. 12F and FIG. 13, firstly, the upper surface of the substrate layer 10 is imprinted with the mold 40, so that the plurality of wire grating units 21 extending in the first direction are formed on the upper surface of the substrate layer 10 (Step S21). Each of the wire grating units 21 has a top surface ST and respectively has a first side surface S1 and a second side surface S2 along two sides of the first direction D1. Then, a metallic or nonmetallic dielectric material is deposited onto the top surface ST and the first side surface S1 of each of the wire grating units 21 (Step S22). Finally, the metallic or nonmetallic dielectric material deposited on the top surface ST of each of the wire grating units 21 is removed (Step S23).

In some embodiments, the material of the substrate layer 10 may be but is not limited to thermoplastic polymers or thermosetting polymers.

In some embodiments, the step that the substrate layer 10 is imprinted with the mold 40 so that a plurality of wire grating units 21 extending in a first direction are formed on an upper surface of the substrate layer 10 includes operations that during imprinting, the substrate layer 10 is heated by a heater 50 so that the substrate layer 10 is cured, and after the substrate layer 10 is cured, the substrate layer 10 is cooled by a cooler 51 so that the substrate layer 10 is separated from the mold 40 and the plurality of wire grating units 21 extending in the first direction are formed on the upper surface of the polymer substrate layer 10.

In some embodiments, the step that metallic or nonmetallic dielectric material is deposited onto the top surface ST and the first side surface S1 of each of the wire grating units 21 may be but is not limited to a step that a target metal 60 is evaporated onto the top surface ST and the first side surface S1 of each of the wire grating units 21 by electron beams emitted from an electronic gun 70.

In some embodiments, the step that the metallic or nonmetallic dielectric material deposited on the top surface ST of each of the wire grating units 21 is removed may be but is not limited to a step that the substrate layer 10 is subjected to plasma etching to remove the metallic or nonmetallic dielectric material from the top surface ST of each of the wire grating units 21.

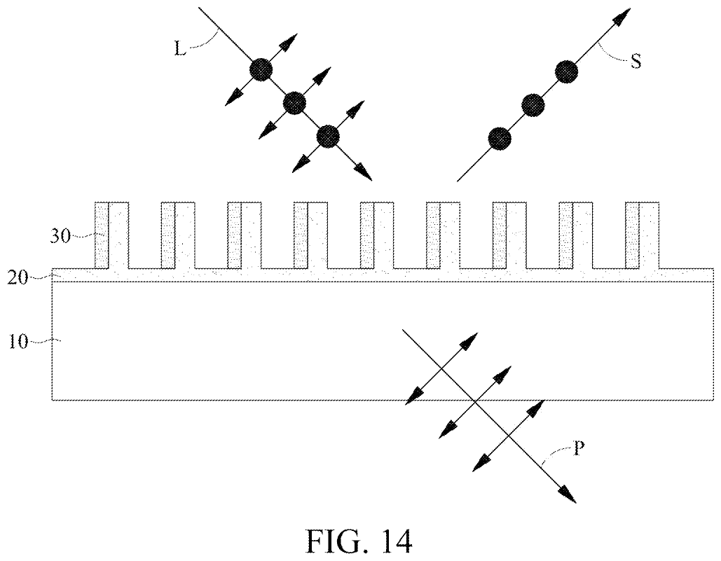

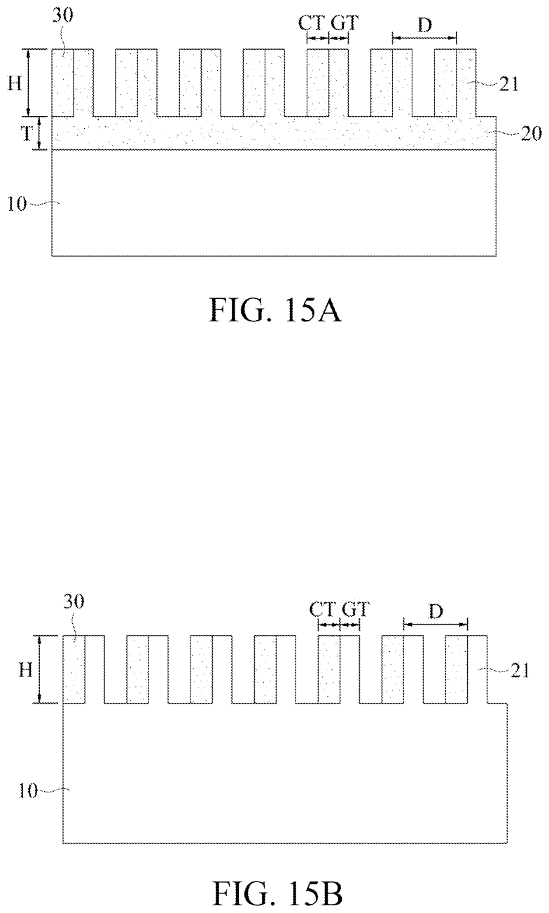

FIG. 14 is a schematic diagram of an embodiment with an unpolarized light source L emitted to the wire grating polarizer 1. FIG. 15A to FIG. 15B are schematic diagrams for a height H of a coated layer 30, a width GT of a wire grating unit 21, a spacing D of a wire grating unit 21, a thickness T of a bottom layer 22 and a width CT of a coated layer 30. Referring to FIG. 14 and FIG. 15A to FIG. 15B, when the unpolarized light source L is emitted to the wire grating polarizer 1, most S waves are reflected after an electric field of S waves of the unpolarized light source parallel to the wire grating structure resonates with free electrons on the plurality of coated layers 30. Most P waves are transmitted since an electric field of the P waves of the unpolarized light source perpendicular to the wire grating structure cannot resonate with free electrons on the plurality of coated layers 30. An extinction ratio ER is a ratio of a penetration rate Tₚ of the P waves to a penetration rate Tₛ of the S waves. A higher extinction ratio ER represents a better separation of S wave and P wave. A formula of the extinction ratio ER is as follows:

$$ER = \frac{{T}_{p}}{{T}_{s}}$$

The penetration rate Tₛ of the S waves, the reflectance Rₛ of the S waves, the penetration rate Tₚ of the P waves, the reflectance Rₚ of the P waves are relevant to the width GT of the wire grating units 21, the spacing D of the wire grating units 21, the height H of the coated layers 30, the width CT of the coated layers 30, the wavelength of the unpolarized light source L and the incidence angle of the unpolarized light source L. The width GT of the wire grating units 21, the spacing D of the wire grating units 21, the height H of the coated layers 30 and the width CT of the coated layers 30 may be adjusted to meet use requirements by adjusting the shape of the mold 40 or the etching degree during the manufacture of the wire grating polarizer 1. In some embodiments, the height H of the coated layers 30 may be but is not limited to 50 to 200 nm, the width GT of the wire grating units 21 may be but is not limited to 10 to 40 nm, the spacing D of the wire grating units 21 may be but is not limited to a value less than 150 nm, the width CT of the coated layers 30 may be but is not limited to 10 to 60 nm, and the thickness T of the bottom layers 22 may be but is not limited to a value less than 10 nm.

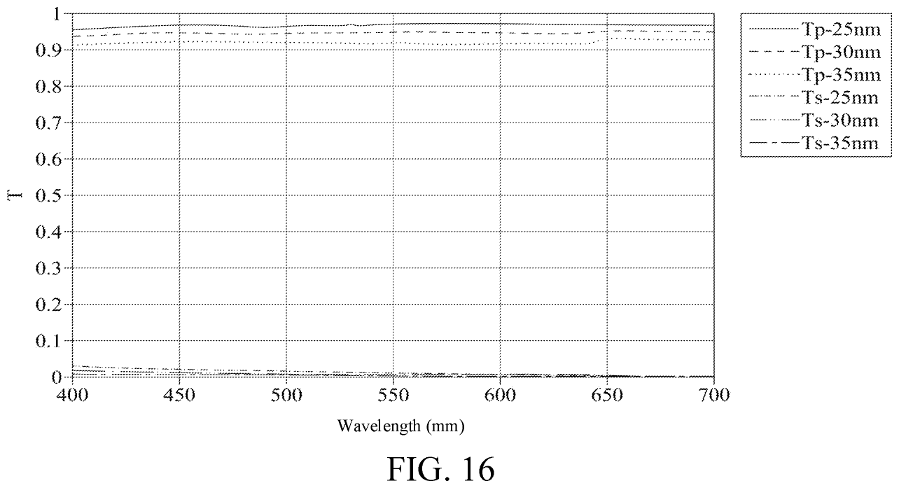

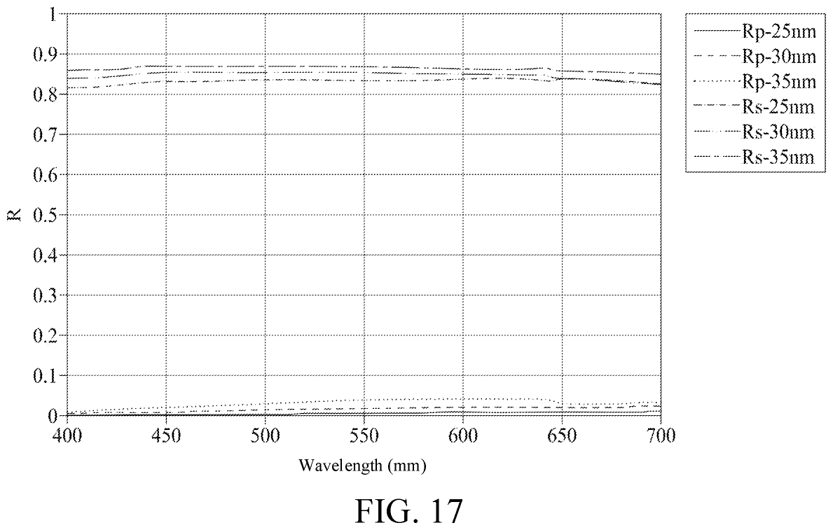

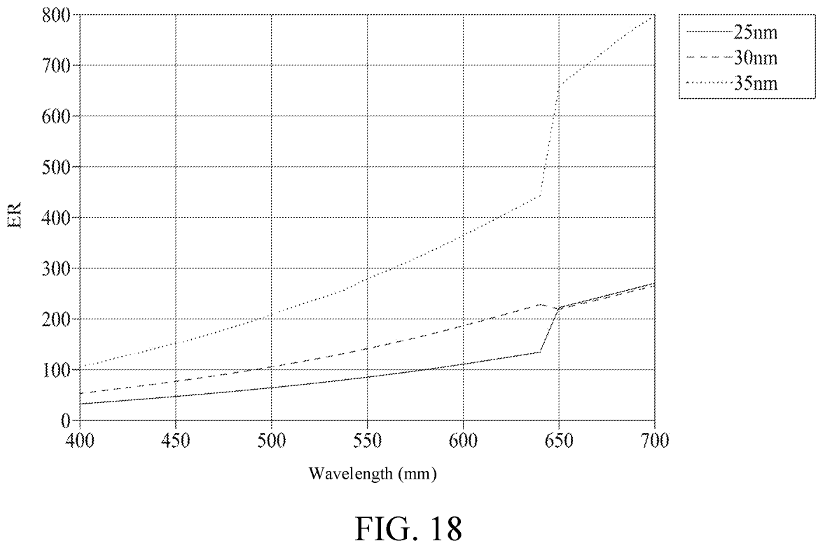

FIG. 16 is a line chart of transmittance Tₛ of S waves and transmittance Tₚ of P waves of the wire grating polarizer 1 at different widths CT of coated layers 30. FIG. 17 is a line chart of reflectance Rₛ of S waves and reflectance Rₚ of P waves of the wire grating polarizer 1 at different widths CT of coated layers 30. FIG. 18 is a line chart of extinction ratios ER of the wire grating polarizer 1 at different widths CT of coated layers 30. In embodiments of FIG. 16 to FIG. 18, the spacing D of the wire grating units 21 is 100 nm, the height H of the coated layers 30 is 100 nm, and the width GT of the wire grating units 21 is 20 nm. A wavelength range of the unpolarized light source L is 400 to 700 nm. The width CT of the coated layers 30 is 25, 30 or 35 nm. Referring to FIG. 16 to FIG. 18, in some embodiments, when the width CT of the coated layers 30 is 35 nm, the wire grating polarizer 1 has the highest extinction ratio.

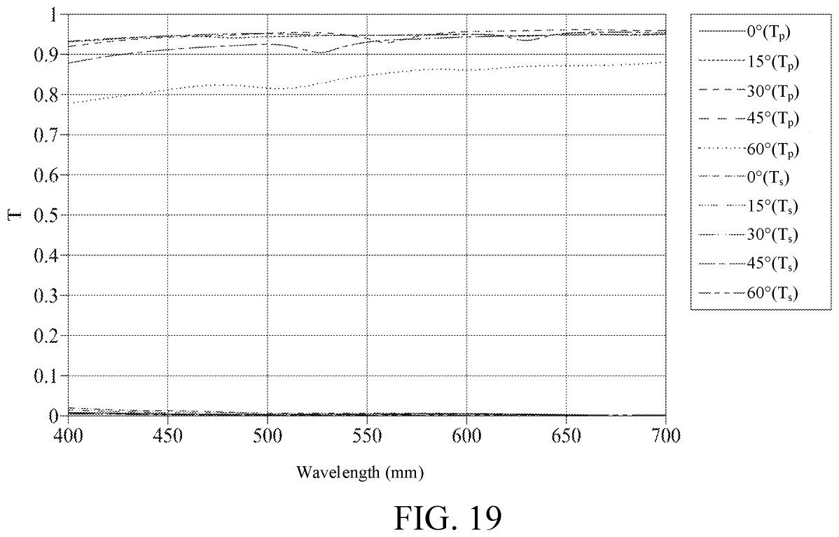

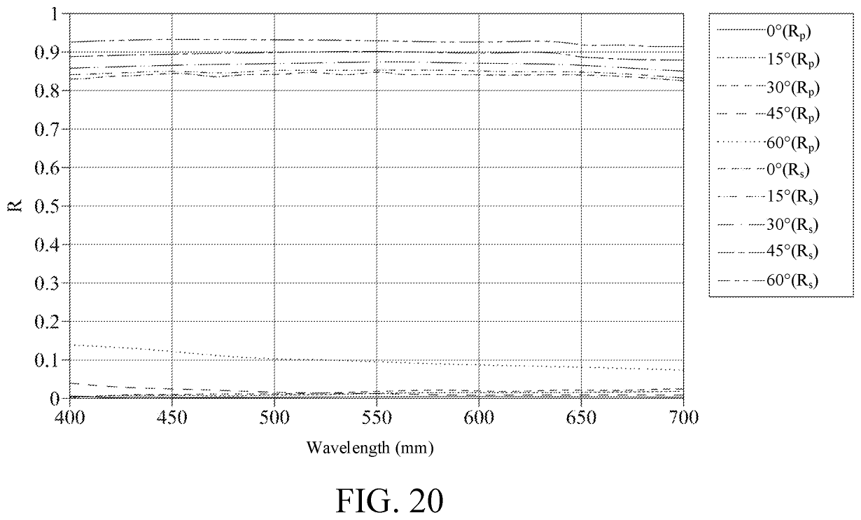

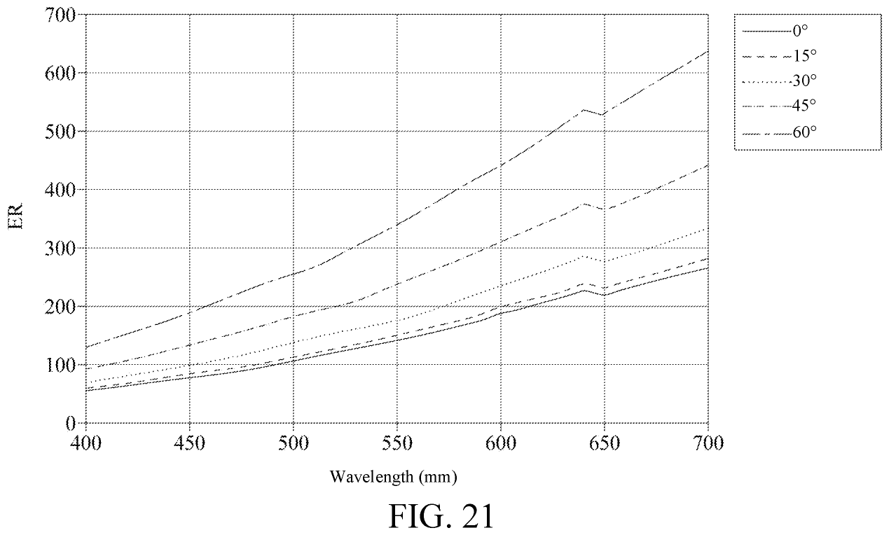

FIG. 19 is a line chart of transmittance Tₛ of S waves and transmittance Tₚ of P waves of the wire grating polarizer 1 at different incidence angles of the unpolarized light source L. FIG. 20 is a line chart of reflectance Rₛ of S waves and reflectance Rₚ of P waves of the wire grating polarizer 1 at different incidence angles of the unpolarized light source L. FIG. 21 is a line chart of extinction ratios ER of the wire grating polarizer 1 at different incidence angles of the unpolarized light source L. In embodiments of FIG. 19 to FIG. 21, the spacing D of the wire grating units 21 is 100 nm, the height of the coated layers 30 is 100 nm, the width GT of the wire grating units 21 is 20 nm, and the width CT of the coated layers 30 is 30 nm. A wavelength range of the unpolarized light source L is 400 to 700 nm. An incidence angle of the unpolarized light source L is 0°, 15°, 30°, 45° or 60°. Referring to FIG. 19 to FIG. 21, in some embodiments, when the incidence angle of the unpolarized light source L is 60°, the wire grating polarizer 1 has the highest extinction ratio.

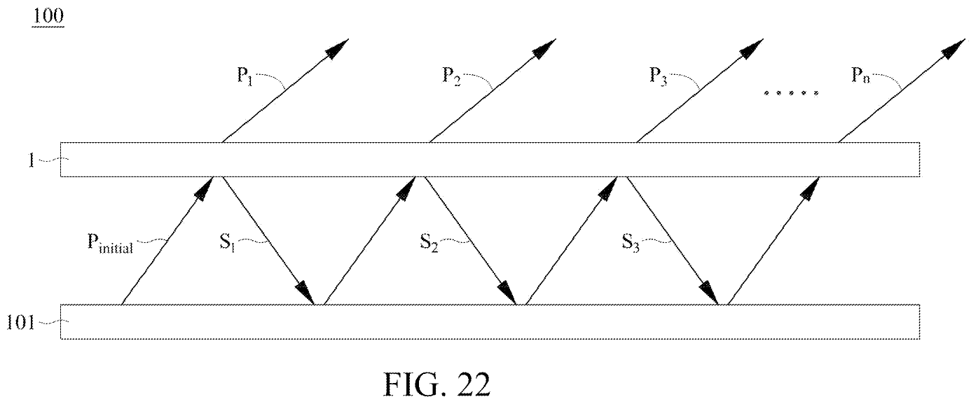

FIG. 22 is a schematic diagram of an embodiment using the wire grating polarizer 1 as a backlight module 100 of a reflective polarizer. Referring to FIG. 22, the backlight module 100 reflects S₁ waves parallel to the wire grating structure of the wire grating polarizer 1 in Pᵢₙᵢₜᵢₐₗ waves emitted into the wire grating polarizer 1 from a reflector plate 101 through the wire grating polarizer 1, and P₁ waves perpendicular to the wire grating structure of the wire grating polarizer 1 in the Pᵢₙᵢₜᵢₐₗ waves transmit through the wire grating polarizer. After being reflected into unpolarized waves through the reflector plate 101, the S₁ waves are emitted to the wire grating polarizer 1, then, the wire grating polarizer 1 reflects the S₂ waves parallel to the wire grating structure of the wire grating polarizer 1 in the unpolarized waves, and the P₂ waves perpendicular to the wire grating structure of the wire grating polarizer 1 in the unpolarized waves transmit through the wire grating polarizer. The backlight module 100 continuously reflects the S waves parallel to the wire grating structure of the wire grating polarizer 1 through the wire grating polarizer 1 and the reflector plate 101, and the P waves perpendicular to the wire grating structure of the wire grating polarizer 1 continuously penetrate through the wire grating polarizer to achieve the repeated recovery and utilization of light rays. The reflectance of the reflector plate 101 is represented by r. A formula of a total penetration rate T_{BLU} of the wire grating polarizer 1 applied to the backlight module 100 is as follows:

$${T}_{BLU} = \frac{{P}_{1} + … {P}_{n}}{{P}_{initial}} = ( \frac{{T}_{p}}{2} ) \frac{1}{1 - r ( \frac{{R}_{s} + {R}_{p}}{2} )}$$

In some embodiments, when the width CT of the coated layers 30 is 35 nm, the wire grating polarizer 1 has the highest total penetration rate T_{BLU}.

In some embodiments, when the width CT of the coated layers 30 is 30 nm, the wire grating polarizer 1 has the highest total penetration rate T_{BLU}.

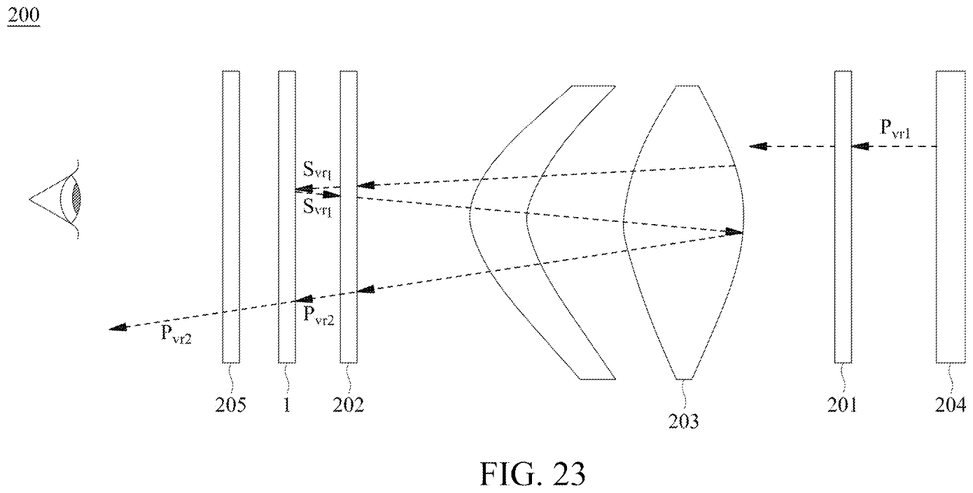

FIG. 23 is a schematic diagram of an embodiment using the wire grating polarizer 1 as a head-mounted VR device 200 of a reflective polarizer. Referring to FIG. 23, the head-mounted VR device 200 transmits Pᵥᵣ₁ waves through a display 204, the Pᵥᵣ₁ waves form right-handed circular polarized light through a wave plate 201, and then pass through a wave plate 202 to form Sᵥᵣ₁ waves and incident to the wire grating polarizer 1. Then, the wave grating polarizer 1 reflects the Sᵥᵣ₁ waves to the wave plate 202 to form right-handed circular polarized light. The Sᵥᵣ₁ waves are reflected by a half-reflecting and half-penetrating mirror 203 to form left-handed circular polarized light, Pᵥᵣ₂ waves are formed through the wave plate 202, and are then emitted to the wire grating polarizer 1, and the Pᵥᵣ₂ waves penetrate through the wire grating polarizer 1. The head-mounted VR device 200 achieves the goal of light path increase through the wire grating polarizer 1. A formula of a total penetration rate T_{VR} of the wire grating polarizer 1 applied to the head-mounted VR device 200 under the condition of not considering the absorption rate between all materials of the head-mounted VR devices 200 is as follows:

T_{VR}=Rₛ×T_{P}

In some embodiments, when the width CT of the coated layers 30 is 25 nm, the wire grating polarizer 1 has the highest total penetration rate T_{VR}.

In some embodiments, when the width CT of the coated layers 30 is 20 nm, the wire grating polarizer 1 has the highest total penetration rate T_{VR}.

In some embodiments, when the total penetration rate T_{VR} of the wire grating polarizer 1 is higher than a threshold value, the head-mounted VR device 200 does not include an absorption polarizer 205.

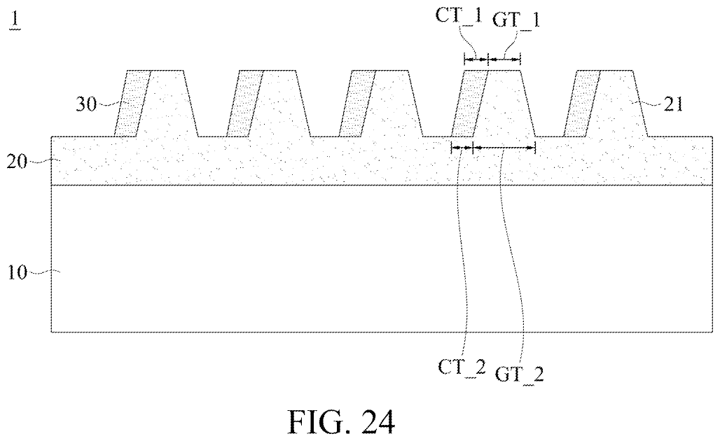

FIG. 24 is a lateral view of another embodiment of the wire grating polarizer 1. Referring to FIG. 24, in some embodiments, a shape of a cross section of each of the wire grating units 21 in a direction perpendicular to the first direction D1 is trapezoidal. In some embodiments, the lower width GT_2 of the wire grating units 21 is between ⅔ times and 1⅓ times of the upper width GT_1 of the wire grating units 21. For example, if the upper width GT_1 of the wire grating units 21 is 30 nm. At this moment, the lower width GT_2 of the wire grating units 21 is between 20 nm and 40 nm. Through experiments, it shows that when the lower width GT_2 of the wire grating units 21 is not between ⅔ times and 1⅓ times of the upper width GT_1 of the wire grating units 21, the extinction ratio of the wire grating polarizer 1 is too low, and the industry requirements could not be met. In some embodiments, the lower width CT_2 of the coated layers 30 is between ¾ times and 1¼ times of the upper width CT_1 of the coated layers 30. For example, if the upper width CT_1 of the coated layers 30 is 40 nm, at this moment, the lower width CT_2 of the coated layers 30 is between 30 nm and 50 nm. Through experiments, it shows that if the lower width CT_2 of the coated layers 30 is not in a range between ¾ times and 1¼ times of the upper width CT_1 of the coated layers 30, the extinction ratio of the wire grating polarizer 1 is too low, and the industry requirements could not be met.

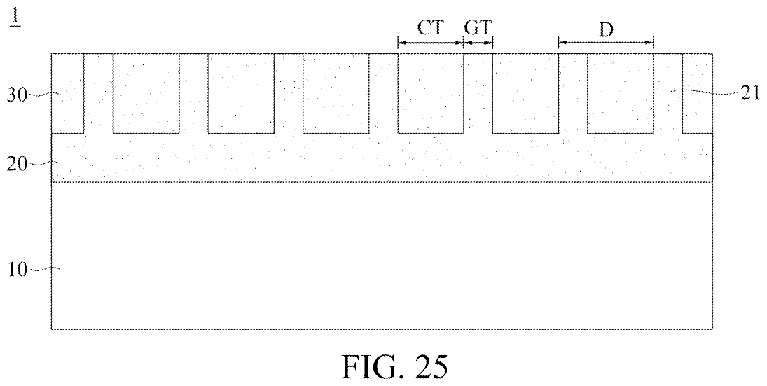

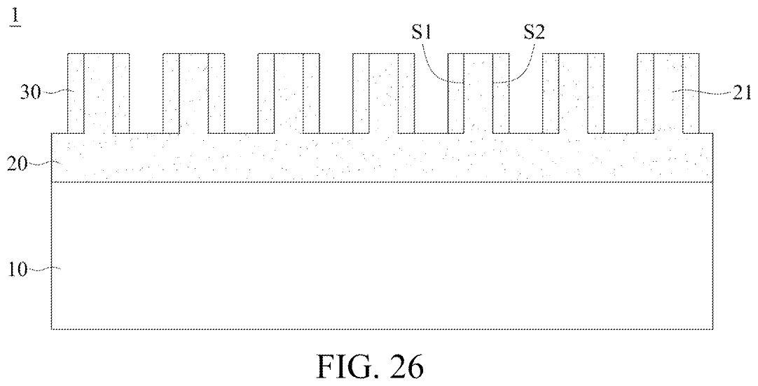

FIG. 25 is a lateral view of another embodiment of the wire grating polarizer 1. Referring to FIG. 25, In some embodiments, the coated layers 30 are respectively formed on the first side surface S1 of each of the wire grating units 21, and the width CT of the coated layers 30 is a value obtained by deducting the width GT of the wire grating units 21 from the spacing D of the wire grating units 21. In other words, a space between the adjacent wire grating units 21 is fully filled with the coated layers 30. For example, if the spacing D of the wire grating units 21 is 100 nm, and the width GT of the wire grating units 21 is 40 nm, at this moment, the width CT of the coated layers 30 is 60 nm. However, through experiments, it shows that the extinction ratio of the wire grating polarizer 1 shown in FIG. 25 is less than the extinction ratio of the wire grating polarizer 1 shown in FIG. 1 and FIG. 2.

FIG. 26 is a lateral view of another embodiment of the wire grating polarizer 1. Referring to FIG. 26, in some embodiments, the plurality of coated layers 30 are respectively formed on the first side surface S1 and the second side surface S2 of each of the wire grating units 21. However, through experiments, it shows that the extinction ratio of the wire grating polarizer 1 shown in FIG. 26 is less than the extinction ratio of the wire grating polarizer 1 shown in FIG. 1 and FIG. 2.

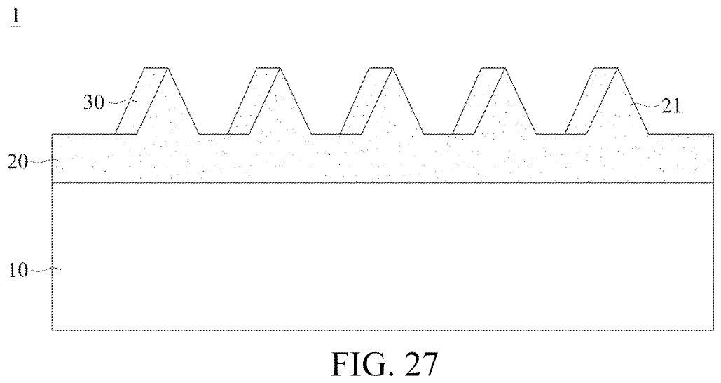

FIG. 27 is a lateral view of another embodiment of the wire grating polarizer 1. Referring to FIG. 27, in some embodiments, a shape of a cross section of each of the wire grating units 21 in a direction perpendicular to the first direction D1 is triangular. However, through experiments, it shows that the extinction ratio of the wire grating polarizer 1 shown in FIG. 27 is less than the extinction ratio of the wire grating polarizer 1 shown in FIG. 1 and FIG. 2.

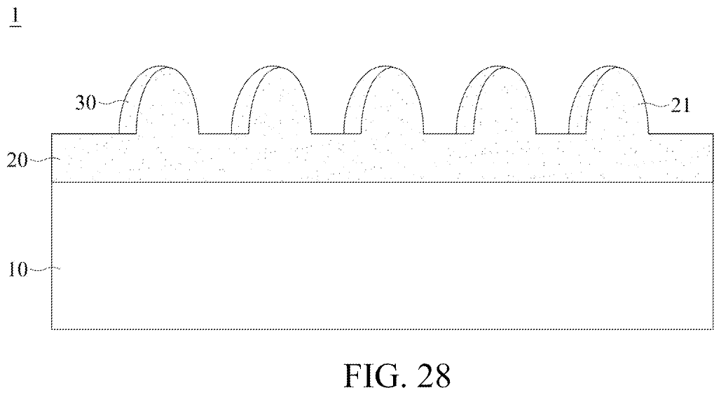

FIG. 28 is a lateral view of another embodiment of the wire grating polarizer 1. Referring to FIG. 28, in some embodiments, a shape of a cross section of each of the wire grating units 21 in a direction perpendicular to the first direction D1 is an arc shape. However, through experiments, it shows that the extinction ratio of the wire grating polarizer 1 shown in FIG. 28 is less than the extinction ratio of the wire grating polarizer 1 shown in FIG. 1 and FIG. 2. Based on the above, in some embodiments, the coated layers 30 of the wire grating polarizer 1 are only formed on the first side surface S1 of each of the wire grating units 21, and the coated layers 30 of the wire grating polarizer 1 are not formed on the top surface ST of each of the wire grating units 21. Therefore, the wire grating polarizer 1 cannot generate a problem of being easily damaged by external since the metal above each of the wire grating units 21 is exposed in the space. Additionally, the width GT of the wire grating units 21, the spacing D of the wire grating units 21, the height H of the coated layers 30 and the width CT of the coated layers 30 may be adjusted by adjusting the shape of the mold 40 or the etching degree during the manufacture of the wire grating polarizer 1, so that the wire grating polarizer 1 may achieve the better extinction ratio ER, total penetration rate T_{BLU} or total penetration rate T_{VR}.

Although the present disclosure has been described in considerable detail with reference to certain preferred embodiments thereof, the disclosure is not for limiting the scope of the invention. Persons having ordinary skill in the art may make various modifications and changes without departing from the scope and spirit of the disclosure. Therefore, the scope of the appended claims should not be limited to the description of the preferred embodiments described above.

What is claimed is:

1. A wire grating polarizer, comprising:
a substrate layer;
a polymer wire grating layer, disposed on the substrate layer and comprising a plurality of wire grating units, the wire grating units being formed on an upper surface of the substrate layer and extending in a first direction, and each of the wire grating units having a top surface and respectively having a first side surface and a second side surface along two sides of the first direction, and
a plurality of coated layers, respectively formed on the first side surface of each of the wire grating units and being made of a metallic or nonmetallic dielectric material.

2. The wire grating polarizer according to claim 1, wherein the polymer wire grating layer further comprises a plurality of bottom layers, the plurality of bottom layers are respectively disposed between two adjacent wire grating units and are in contact with the upper surface of the substrate layer, and an upper surface of each of the bottom layers is lower than the top surface of each of the wire grating units.

3. The wire grating polarizer according to claim 1, wherein the material of the substrate layer is different from the material of the polymer wire grating layer.

4. The wire grating polarizer according to claim 1, wherein a height of the wire grating units is 50 to 200 nm, a width of the wire grating units is 10 to 40 nm, a spacing of the wire grating units is less than 150 nm, and a width of the coated layers is 10 to 60 nm.

5. The wire grating polarizer according to claim 1, wherein a shape of a cross section of each of the wire grating units in a direction perpendicular to the first direction is rectangular.

6. The wire grating polarizer according to claim 4, wherein a shape of a cross section of each of the wire grating units in a direction perpendicular to the first direction is rectangular.

7. A manufacturing method of a wire grating polarizer, comprising:
disposing a polymer layer on a substrate layer;
imprinting the polymer layer with a mold to form a polymer wire grating layer, wherein the polymer wire grating layer comprises a plurality of bottom layers and a plurality of wire grating units extending in a first direction, the bottom layers are respectively positioned between two adjacent wire grating units and are in contact with the upper surface of the substrate layer, each of the wire grating units has a top surface and respectively has a first side surface and a second side surface along two sides of the first direction, and an upper surface of each of the bottom layers is lower than the top surface of each of the wire grating units;
depositing a metallic or nonmetallic dielectric material onto the top surface and the first side surface of each of the wire grating units; and
removing the metallic or nonmetallic dielectric material deposited on the top surface of each of the wire grating units.

8. The manufacturing method of a wire grating polarizer according to claim 7, wherein after a step of imprinting the polymer layer, the method further comprises:
etching the polymer wire grating layer to remove the bottom layers.

9. The manufacturing method of a wire grating polarizer according to claim 7, wherein the material of the polymer layer is selected from thermoplastic polymers, thermosetting polymers or photocuring polymers.

10. The manufacturing method of the wire grating polarizer according to claim 7, wherein a height of the wire grating units is 50 to 200 nm, a width of the wire grating units is 10 to 40 nm, a spacing of the wire grating units is less than 150 nm, and a width of the metallic or nonmetallic dielectric material is 10 to 60 nm.

11. The manufacturing method of a wire grating polarizer according to claim 6, wherein a shape of a cross section of each of the wire grating units in a direction perpendicular to the first direction is rectangular.

12. The manufacturing method of a wire grating polarizer according to claim 9, wherein a shape of a cross section of each of the wire grating units in a direction perpendicular to the first direction is rectangular.

13. A wire grating polarizer, comprising:
a substrate layer, comprising a plurality of wire grating units extending in a first direction, each of the wire grating units having a top surface and a first side surface and a second side surface along two sides of the first direction; and
a plurality of coated layers, respectively formed on the first side surface of each of the wire grating units and being made of a metallic or nonmetallic dielectric material.

14. The wire grating polarizer according to claim 13, wherein a height of the wire grating units is 50 to 200 nm, a width of the wire grating units is 10 to 40 nm, a spacing of the wire grating units is less than 150 nm, and a width of the coated layers is 10 to 60 nm.

15. The wire grating polarizer according to claim 13, wherein a shape of a cross section of each of the wire grating units in a direction perpendicular to the first direction is rectangular.

16. A manufacturing method of a wire grating polarizer, comprising:
imprinting an upper surface of a substrate layer with a mold so that a plurality of wire grating units extending in a first direction are formed on an upper surface of the substrate layer, wherein each of the wire grating units has a top surface and respectively has a first side surface and a second side surface along two sides of the first direction;
depositing a metallic or nonmetallic dielectric material onto the top surface and the first side surface of each of the wire grating units; and
removing the metallic or nonmetallic dielectric material deposited on the top surface of each of the wire grating units.

17. The manufacturing method of a wire grating polarizer according to claim 16, wherein a height of the wire grating units is 50 to 200 nm, a width of the wire grating units is 10 to 40 nm, a spacing of the wire grating units is less than 150 nm, and a width of the metallic or nonmetallic dielectric material is 10 to 60 nm.

18. The manufacturing method of a wire grating polarizer according to claim 16, wherein a shape of a cross section of each of the wire grating units in a direction perpendicular to the first direction is rectangular.
